(19) United States
(12) Patent Application Publication
(10) Pub. No.: US 2018/0358374 A1
(43) Pub. Date: Dec. 13, 2018

(54) VERTICAL MEMORY DEVICE

(71) Applicant: Samsung Electronics Co., Ltd., Suwon-si (KR)

(72) Inventors: Kwang Soo KIM, Hwaseong-si (KR); Hyun Suk KIM, Suwon-si (KR); Soon Hyuk HONG, Seongnam-si (KR); Doo Hee HWANG, Uiwang-si (KR)

(21) Appl. No.: 15/868,084

(22) Filed: Jan. 11, 2018

(30) Foreign Application Priority Data
Jun. 13, 2017 (KR) 10-2017-0073924

(51) Int. Cl. H01L 27/11582; H01L 29/423; H01L 29/10; H01L 23/532; H01L 23/528; H01L 27/11565; H01L 29/792

(52) U.S. Cl. CPC H01L 27/11582; H01L 29/4234; H01L 29/1037; H01L 27/11573; H01L 23/5283; H01L 27/11565; H01L 29/7926; H01L 23/53271

(57) ABSTRACT

A vertical memory device includes a gate structure including a plurality of gate electrode layers stacked on a substrate, a plurality of channel structures penetrating through the gate structure and extending in a direction perpendicular to an upper surface of the substrate, a common source line penetrating the gate structure and extending in a first direction, a metal line extended above the common source line in the first direction, and a plurality of connection portions interposed between the metal line and the common source line.

### CROSS-REFERENCE TO RELATED APPLICATION

This application claims priority under 35 U.S.C. § 119 to Korean Patent Application No. 10-2017-0073924, filed on Jun. 13, 2017 in the Korean Intellectual Property Office, the disclosure of which is incorporated by reference herein in its entirety.

### TECHNICAL FIELD

The present inventive concept relates to a vertical memory device.

### DESCRIPTION OF RELATED ART

Electronic products demand high-density semiconductor memory devices. To increase the degree of integration in semiconductor memory devices, memory cells having a vertical transistor structure are vertically stacked on a substrate.

### SUMMARY

According to an example embodiment of the present inventive concept, a vertical memory device comprises a gate structure including a plurality of gate electrode layers stacked on a substrate, a plurality of channel structures penetrating through the gate structure and extending in a direction perpendicular to an upper surface of the substrate, a common source line penetrating the gate structure and extending in a first direction, a metal line extended above the common source line in the first direction, and a plurality of connection portions interposed between the metal line and the common source line.

According to an example embodiment of the present inventive concept, a vertical memory device comprises a plurality of gate electrode layers stacked on a substrate, a common source line penetrating the plurality of gate electrode layers and extended in a first direction, at least one metal line disposed above the common source line, and a plurality of connection portions interposed between the at least one metal line and the common source line.

According to an example embodiment of the present inventive concept, a vertical memory device comprises a plurality of gate electrode layers stacked on a substrate, a common source line penetrating the plurality of gate electrode layers and extended in a first direction, at least one metal line extended above the common source line in the first direction, a plurality of source strapping lines disposed on the at least one metal line at a first interval in the first direction, and a plurality of connection portions interposed between the at least one metal line and the common source line at a second interval, narrower than the first interval.

### BRIEF DESCRIPTION OF DRAWINGS

These and other features of the present inventive concept will become more apparent by describing in detail exemplary embodiments thereof with reference to the accompanying drawings of which:

FIG. 1 is a schematic conceptual top view of a vertical memory device according to an example embodiment;

FIG. 2 is a schematic top view of a vertical memory device according to an example embodiment;

FIGS. 3 to 5 are schematic cross-sectional views of a vertical memory device according to an example embodiment;

FIGS. 6 and 7 are schematic cross-sectional views of a vertical memory device according to example embodiments;

FIG. 8 is a schematic top view of a vertical memory device according to another example embodiment;

FIGS. 9 and 10 are schematic cross-sectional views of a vertical memory device according to another example embodiment;

FIGS. 11 and 12 are schematic cross-sectional views of a vertical memory device according to further example embodiments;

FIG. 13 is a schematic top view of a vertical memory device according to another example embodiment;

FIGS. 14 to 16 are schematic cross-sectional views of a vertical memory device according to another example embodiment; and

FIGS. 17 to 21 are schematic cross-sectional views of a vertical memory device according to further example embodiments.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. Like reference numerals may refer to the like elements throughout the specification and drawings.

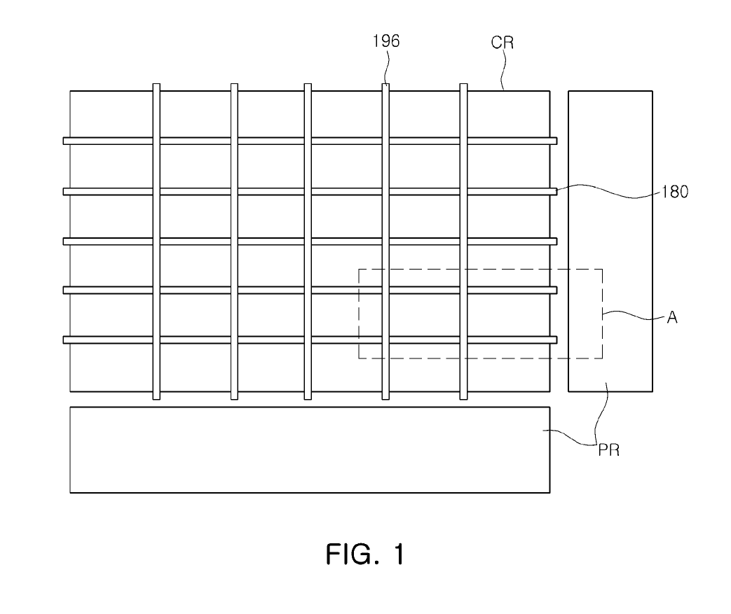

FIG. 1 is a schematic conceptual top view of a vertical memory device according to an example embodiment.

With reference to FIG. 1, the vertical memory device according to an example embodiment includes a cell region CR in which a plurality of memory cells are formed, and a peripheral circuit region PR in which peripheral circuits to drive memory cells are formed. A row decoder circuit, a column decoder circuit, a page buffer circuit, or the like, may be disposed in the peripheral circuit region PR. FIG. 1 is merely exemplary, and a disposition of the peripheral circuit region PR is not limited to the position illustrated in FIG. 1. A plurality of common source lines 180 extended in a first direction are disposed in the cell region CR. The common source lines 180 are disposed at a predetermined interval in a second direction intersecting the first direction. The cell region CR may be divided into a plurality of regions by the common source lines 180.

The cell region CR includes a plurality of source strapping lines 194 extended in the second direction, intersecting the first direction. The source strapping lines 194 are disposed at a predetermined interval in the first direction. The source strapping lines 194 each may be electrically connected to the common source lines 180. Each of the source strapping lines 194 is illustrated as being disposed to be longer than a width of the cell region CR in the second direction, but is not limited thereto.

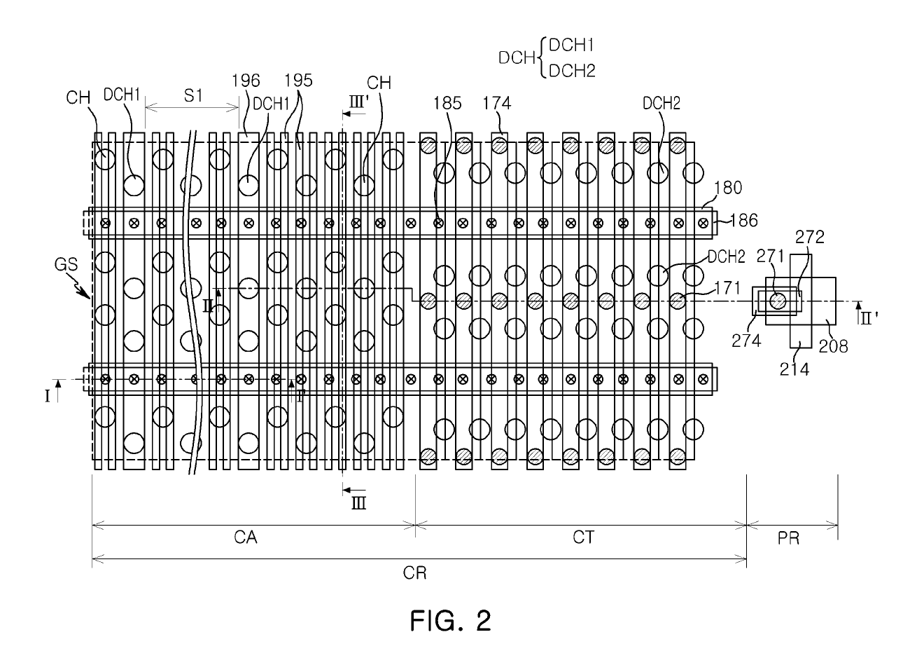

FIG. 2 is a schematic top view of a vertical memory device according to an example embodiment. FIG. 2 illustrates area A of FIG. 1.

With reference to FIG. 2, the vertical memory device according to an example embodiment includes a cell array region CA in which a plurality of memory cells are formed, a connection region CT in which gate electrodes of the plurality of memory cells are formed to be electrically connected to wirings, and a peripheral circuit region PR in which peripheral circuits controlling the plurality of memory cells are formed. The cell array region CA and the connection region CT form the cell region CR.

A gate structure GS is divided into a plurality of regions by the common source lines 180 extended in the first direction and is disposed in the cell array region CA and the connection region CT. The gate structure GS may include a plurality of gate electrode layers and a plurality of mold insulating layers, alternately and vertically stacked on a substrate. The first direction and the second direction are in parallel to a top surface of the substrate. The common source lines 180 are continuously extended in the cell array region CA and the connection region CT along the first direction. The common source lines 180 are spaced apart from each other along the second direction. The common source lines 180 may be electrically connected to the substrate.

A plurality of metal lines 186 are disposed on the common source lines 180. For example, each of the metal lines 186 is disposed on one of the common source lines 180. A plurality of connection portions 185 may be interposed between the metal lines 186 and the common source lines 180. The metal lines 186 may be electrically connected to the common source lines 180 by the connection portions 185. For example, one of the metal lines 186, one of the common source line 180 and the connection portions 185 overlap vertically each other. The connection portions 185 may be interposed between one of the metal lines 186 and one of the common source lines 180 to connect electrically one of the metal lines 186 and one of the common source lines 180. The connection portions 185 are arranged along the first direction.

The source strapping lines 194 intersecting the common source lines 180 are disposed in the cell array region CA. The source strapping lines 194 are extended in the second direction intersecting the first direction. The source strapping lines 194 are disposed at a first interval Si in the first direction.

A plurality of channel structures CH penetrating through the gate structure GS to be connected to the substrate are disposed in the cell array region CA. A plurality of dummy channel structures DCH include a plurality of first dummy channel structures DCH1 and a plurality of second dummy channel structures DCH2. The first dummy channel structures DCH1 penetrating through the gate structure GS to be connected to the substrate and a plurality of gate contact plugs 171 are disposed in the connection region CT. The second dummy channel structures DCH2 disposed below or adjacent to the source strapping lines 194 are disposed in the cell array region CA. For example, the second dummy channel structures DCH2 overlap vertically the source strapping lines 194. The dummy channel structures DCH may have a structure the same as or similar to that of the plurality of channel structures CH.

The channel structures CH may be disposed in a plurality of columns in the cell array region CA. For example, FIG. 2 illustrates that the channel structures CH are arranged in four columns between two common source lines of the common source lines 180. The four columns of the channel structures CH are extended in the first direction. The channel structures CH are disposed in a zigzag form along the first direction. A disposition form of the channel structures CH is not limited to FIG. 2 and may be variously modified.

The gate structure GS may form a stepped structure including a plurality of step portions in the connection region CT. The stepped structure may be formed in such a manner that the plurality of gate electrode layers and the plurality of mold insulating layers of the gate structure GS are extended to have different lengths in the first direction. The first dummy channel structures DCH1 may be disposed adjacent to end portions of step portions. The first dummy channel structures DCH1 are disposed between two adjacent common source lines of the common source lines 180. The first dummy channel structures DCH1 are disposed in two columns along the first direction as an example in FIG. 2, but a disposition form of the first dummy channel structures DCH1 is not limited thereto. For example, the first dummy channel structures DCH1 may be disposed adjacent to the end portion of the step portions, and the second dummy channel structures DCH2 may be disposed to be spaced apart from the end portions of the step portions.

The channel structures CH may be electrically connected to a plurality of bit lines 195, while the dummy channel structures DCH need not be electrically connected to the bit lines 195. For example, the dummy channel structures DCH need not overlap the bit lines 195. Thus, the dummy channel structures DCH need not form a memory cell to which a read/write operation, or the like, may be performed.

A plurality of gate contact plugs 171 are electrically connected to gate electrode layers and are disposed in the connection region CT. A plurality of gate wirings 174 are disposed above the gate contact plugs 171. The gate wirings 174 are extended in the second direction. The gate wirings 174 may be electrically connected to the gate contact plugs 171.

In the meantime, a plurality of circuit transistors may be disposed in the peripheral circuit region PR. FIG. 2 illustrates a single circuit transistor for the sake of convenience. A circuit gate electrode 214, a source/drain region 208 disposed on both sides of the circuit gate electrode 214, a contact plug 271 connected to the source/drain region 208, and a first circuit wiring 272 and a second circuit wiring 274, connected to the contact plug 271 are disposed in the peripheral circuit region PR.

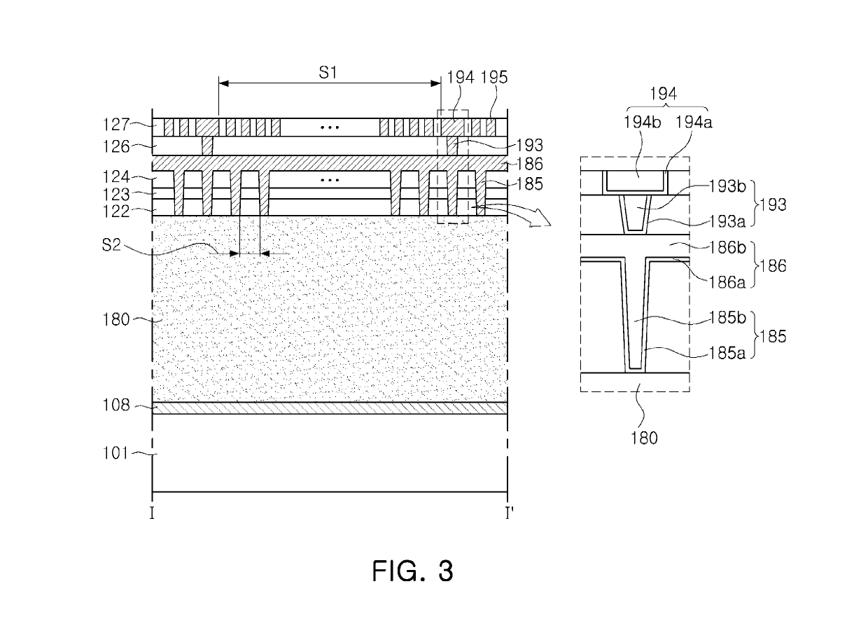

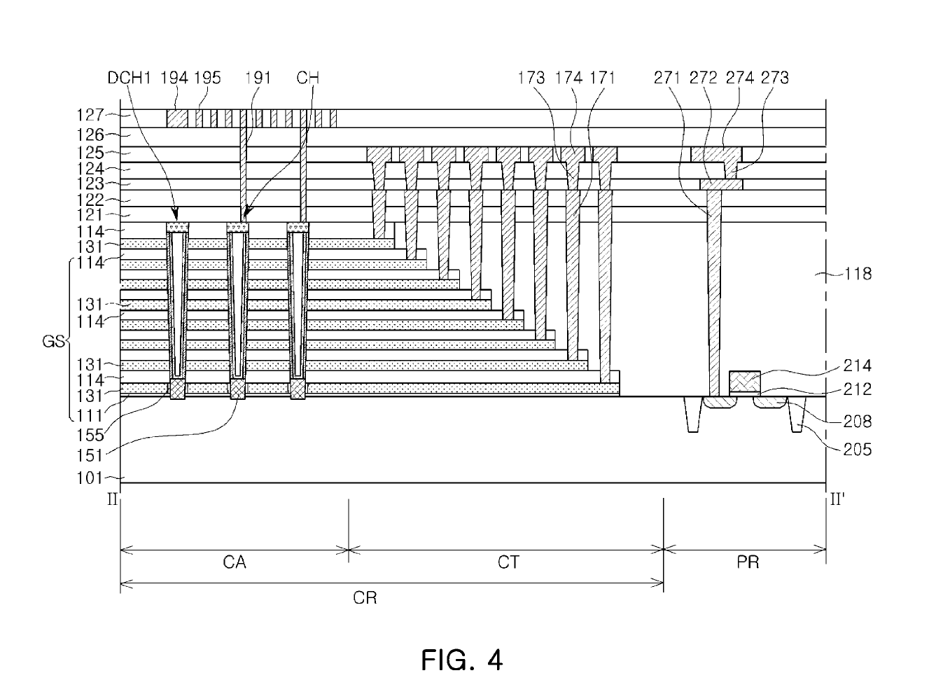

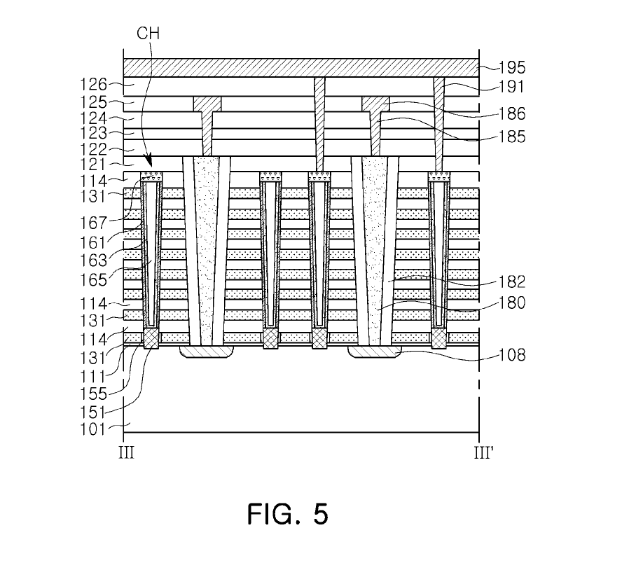

FIGS. 3 to 5 are schematic cross-sectional views of a vertical memory device according to an example embodiment. FIG. 3 is a cross-sectional view taken along line I-I′ of FIG. 2, FIG. 4 is a cross-sectional view taken along line II-IP of FIG. 2, and FIG. 5 is a cross-sectional view taken along line of FIG. 2.

With reference to FIGS. 3 to 5, the vertical memory device includes a plurality of gate electrode layers 131 disposed to be spaced apart from each other in a direction (a third direction) perpendicular to a substrate 101 and stacked on the substrate 101. The substrate 101 may include a semiconductor material, such as a group IV semiconductor, a group III-V compound semiconductor, and a group II-VI compound semiconductor. The gate electrode layers 131 are extended in the first direction and are disposed in the cell array region CA and the connection region CT. The channel structures CH penetrating through the plurality of gate electrode layers 131 are disposed in the cell array region CA. The gate contact plugs 171 electrically connected to the gate electrode layers 131 are disposed in the connection region CT.

A plurality of mold insulating layers 114 are interposed between the gate electrode layers 131. A buffer insulating layer 111 is disposed between a lowermost gate electrode layer of the gate electrode layers 131 and the substrate 101. The buffer insulating layer 111, the gate electrode layers 131, and the mold insulating layers 114 form the gate structure GS. The gate electrode layers 131 may include a metal, a metallic nitride, a metallic silicide, polycrystalline silicon, or combinations thereof. For example, the metal may include tungsten (W) or copper (Cu). For example, the metal silicide may include silicon (Si) and a metal selected from among cobalt (Co), nickel (Ni), hafnium (Hf), platinum (Pt), W, titanium (Ti), or combinations thereof. For example, the metal nitride may include a tungsten nitride (WN), a tantalum nitride (TaN), a titanium nitride (TiN), or combinations thereof. The buffer insulating layer 111 and the mold insulating layers 114 may include a silicon oxide.

The vertical memory device includes the connection region CT, a first interlayer insulating layer 118 disposed in the peripheral circuit region PR, and second to eighth interlayer insulating layers 121 to 127. The second to eighth interlayer insulating layers 121 to 127 are disposed on the gate structure GS and the first interlayer insulating layer 118. The first interlayer insulating layer 118 and the second to eighth interlayer insulating layers 121 to 127 may include a silicon oxide or a low-k dielectric material.

The number of gate electrode layers 131 is not limited to FIGS. 4 and 5. As storage capacity of the vertical memory device increases, the number of gate electrode layers 131 forming memory cells may increase. For example, the gate electrode layers 131 having tens to hundreds of layers may be stacked on the substrate 101.

The gate electrode layers 131 may be extended to have different lengths in the first direction, to form a stepped structure. The mold insulating layers 114 may form a stepped structure together with the gate electrode layers 131.

The vertical memory device includes the common source lines 180 dividing the gate electrode layers 131. The common source lines 180 are disposed in the cell array region CA and the connection region CT, while an insulating layer 182 is disposed on a side wall of each of the common source lines 180. The insulating layer 182 may isolate the common source lines 180 from the gate electrode layers 131. The insulating layer 182 may include silicon oxide (SiO₂), silicon nitride (Si₃N₄), silicon oxynitride (SiON), or combinations thereof. The common source lines 180 and the insulating layer 182 may be extended in the first direction. The common source lines 180 are extended to the substrate 101, so that the common source lines 180 are electrically connected to a plurality of impurity regions 108 formed on the substrate 101. For example, one of the common source lines 180 penetrates the gate electrode layers 131 and the mold insulating layers 114 to be in contact with one of the impurity regions 108. The common source lines 180 may be formed of a conductive material such as a metal including W, Cu, Ti, or aluminum (Al), a doped semiconductor material, and a conductive metal nitride material. In a case in which the common source lines 180 are provided as a doped semiconductor material, the common source lines 180 may be formed of a polycrystalline silicon doped with impurities which are the same type of impurities as those of the impurity regions 108. The impurity concentration of the common source lines 180 may be greater than the impurity concentration of the impurity regions 108.

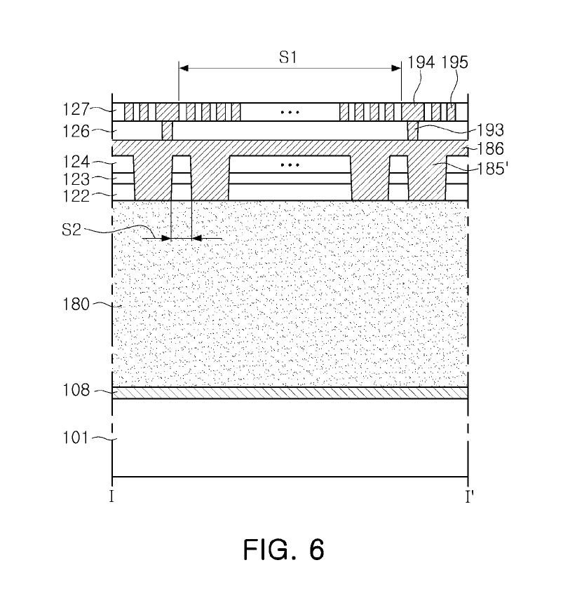

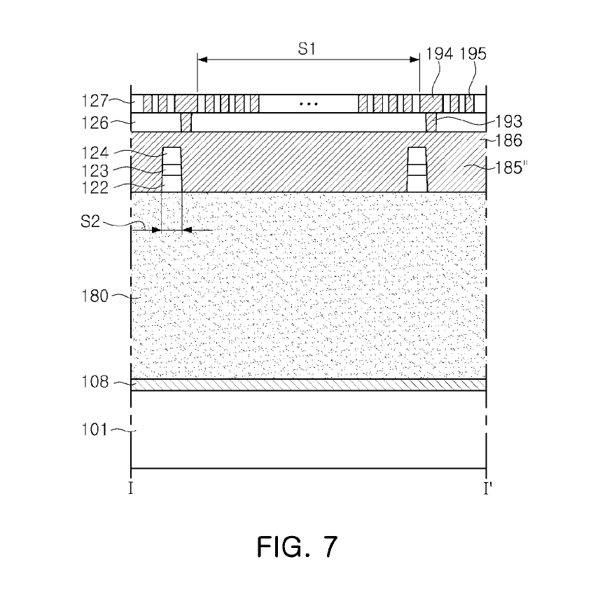

The vertical memory device includes the metal lines 186 extended above the common source lines 180 in the first direction and the connection portions 185 interposed between the metal lines 186 and the common source lines 180. The connection portions 185 penetrate through a third interlayer insulating layer 122, a fourth interlayer insulating layer 123, and a fifth interlayer insulating layer 124 to be electrically connected to the common source lines 180. The connection portions 185 may have a circular horizontal cross section. Alternatively, with reference to FIG. 6, a plurality of connection portions 185′ may be further extended in the first direction, as compared with the connection portions 185 of FIG. 3, and may have an oval horizontal cross section. Alternatively, with reference to FIG. 7, a plurality of connection portions 185″ may be further extended in the first direction, as compared with the plurality of connection portions 185′ of FIG. 6, and may have a rectangular horizontal cross section. According to example embodiments, contact resistance between the common source lines 180 and the connection portions 185, the connection portions 185′, or the connection portions 185″ may be reduced, and a level of noise of the common source lines 180 may be reduced.

The vertical memory device includes the source strapping lines 194 connected to the metal lines 186, disposed at the first interval S1 in the first direction, and extended in the second direction intersecting the first direction. The connection portions 185 are disposed at a second interval S2 narrower than the first interval Si in the first direction.

A plurality of contact plugs 193 are disposed between the source strapping lines 194 and the metal lines 186, connecting the source strapping lines 194 to the metal lines 186. For example, each of the contact plugs 193 connects electrically one of the source strapping lines 194 to one of the metal lines 186. The contact plugs 193 penetrate through a seventh interlayer insulating layer 126 to be connected to the metal lines 186.

The bit lines 195 extended in the second direction are disposed between the source strapping lines 194. A plurality of channel contact plugs 191 connecting the bit lines 195 to the channel structures CH are disposed in the cell array region CA. Each of the bit lines 195 is connected to two channel contact plugs of the channel contact plugs 191 disposed adjacent to each other in the second direction on both sides of one of the common source lines 180. (FIG. 5). The source strapping lines 194 are disposed on the same level as the bit lines 195 in a vertical direction. The metal lines 186 may be disposed on a level lower than the bit lines 195 in the vertical direction.

With reference to an enlarged view of FIG. 3, the metal lines 186 and the connection portions 185 may be formed using a dual damascene process, while the contact plugs 193, the source strapping lines 194, and the bit lines 195 may be formed using a single damascene process. Alternatively, in an example embodiment, each of the metal lines 186 and the connection portions 185 may be formed using a single damascene process. Barrier layers 185a, 186a, 193a, and 194a may include a conductive metal nitride, such as titanium nitride (TiN), while metal layers 185b, 186b, 193b, and 194b may include a metal, such as W. The barrier layer 185a of each of the connection portions 185 is in contact with one of the commons source lines 180.

The gate wirings 174 are disposed above the gate contact plugs 171. A plurality of gate connection portions 173 connecting the gate contact plugs 171 to the gate wirings 174 are disposed in the connection region CT. The gate wirings 174 and the gate connection portions 173 may be formed using a dual damascene process. The gate connection portions 173 penetrate through the fourth interlayer insulating layer 123 and the fifth interlayer insulating layer 124 to be connected to the gate contact plugs 171.

A circuit transistor including a circuit gate insulating layer 212, a circuit gate electrode 214, and a source/drain region 208 is disposed in the peripheral circuit region PR. A contact plug 271 connected to the source/drain region 208 and a first circuit wiring 272 and a second circuit wiring 274, connected to the contact plug 271, are disposed in the peripheral circuit region PR. A circuit connection portion 273 is interposed between the first circuit wiring 272 and the second circuit wiring 274. The second circuit wiring 274 and the circuit connection portion 273 are formed using a dual damascene process.

Each of the channel structures CH disposed in the cell array region CA includes an epitaxial layer 151, a gate insulating layer 161, a channel layer 163, a filled insulating layer 165, and a contact pad 167. (FIG. 5) The dummy channel structures DCH have a structure the same as or similar to that of the channel structures CH.

The epitaxial layer 151 is in contact with the substrate 101, a lower portion of the channel layer 163 is in contact with the epitaxial layer 151 to be electrically connected thereto, and an upper portion of the channel layer 163 is in contact with the contact pad 167 to be electrically connected thereto. For example, the channel layer 163 may electrically connect the contact pad 167 to the epitaxial layer 151.

The gate insulating layer 161 may be formed to surround an external side surface of the channel layer 163. The gate insulating layer 161 may include a tunneling layer, a charge storage layer, and a blocking layer, disposed from the external side surface of the channel layer 163 in sequence.

The tunneling layer may, for example, include a silicon oxide. The charge storage layer may, for example, include a silicon nitride. The blocking layer may include silicon oxide (SiO₂), silicon nitride (Si₃N₄), silicon oxynitride (SiON), or a high-k dielectric material. The high-k dielectric material may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The channel layer 162 may have a pipe form with a closed lower end portion and an open upper end. An internal space of the channel layer 163 is filled with the filled insulating layer 165. The channel layer 163 may include a semiconductor material including polycrystalline silicon, monocrystalline silicon, or the like.

A ground selection gate insulating layer 155 may be locally disposed between the epitaxial layer 151 and a lowermost gate electrode layer of the gate electrode layers 131. The ground selection gate insulating layer 155 may be formed in such a manner that a portion of the epitaxial layer 151 is oxidized.

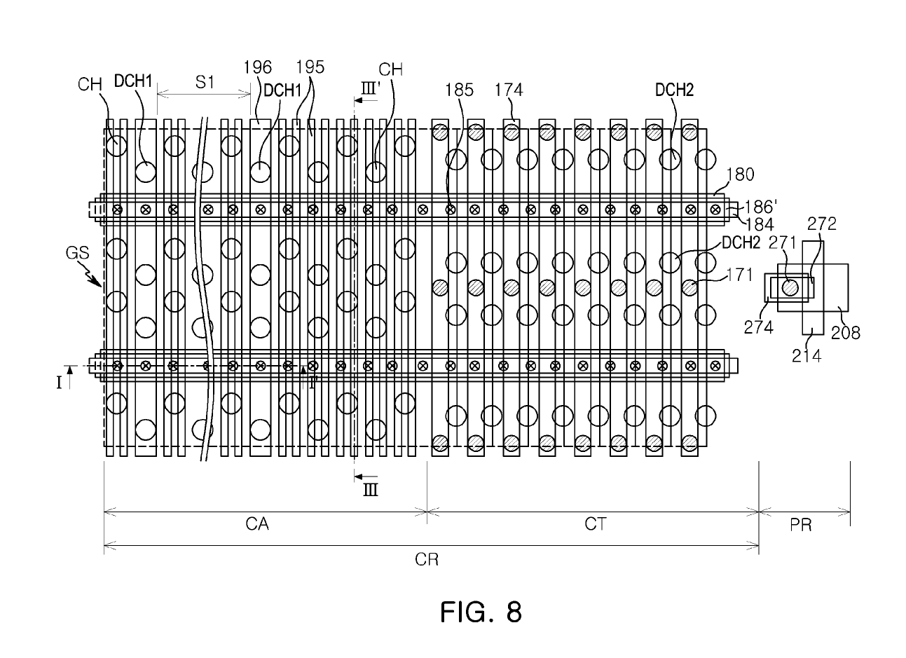

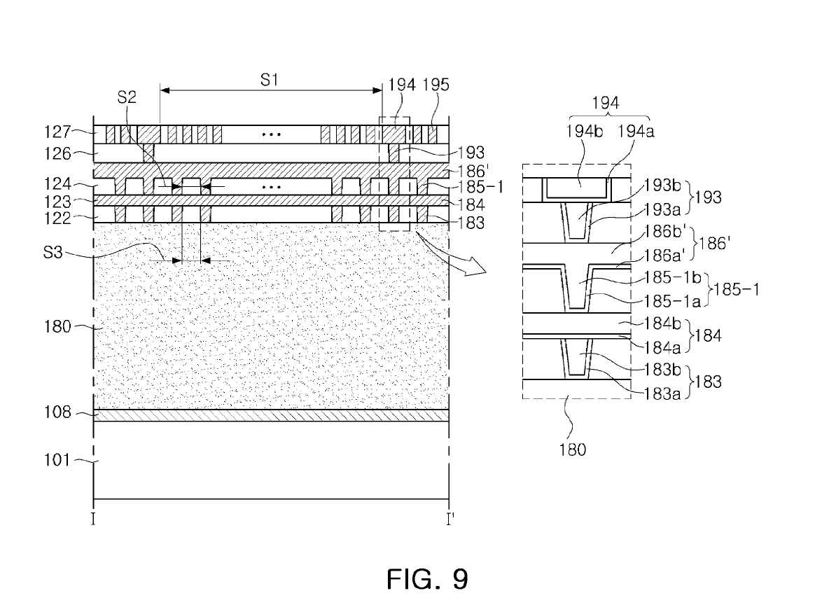

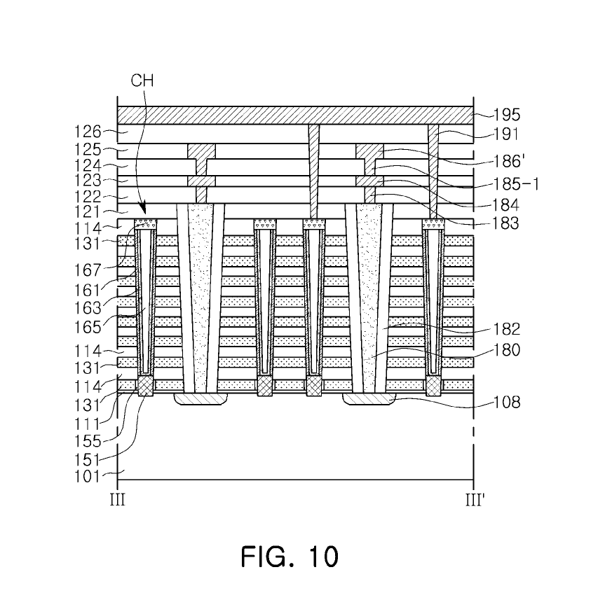

FIG. 8 is a schematic top view of a vertical memory device according to another example embodiment. FIGS. 9 and 10 are schematic cross-sectional views of a vertical memory device according to another example embodiment. FIG. 9 is a cross-sectional view taken along line I-I′ of FIG. 8, and FIG. 10 is a cross-sectional view taken along line of FIG. 8.

The vertical memory device illustrated in FIGS. 8 to 10 will be described, compared with the vertical memory device illustrated in FIGS. 2 to 5, based on differences therebetween. Unlike the vertical memory device illustrated in FIGS. 2 to 5, the vertical memory device illustrated in FIGS. 8 to 10 may include two metal lines on the common source lines 180.

With reference to FIGS. 8 to 10, the vertical memory device includes a plurality of first metal lines 186′ and a plurality of second metal lines 184 extended on the common source lines 180 in the first direction. The second metal lines 184 are interposed between the first metal lines 186′ and the common source lines 180 and are extended in the first direction. In addition, the vertical memory device includes a plurality of first connection portions 185-1 interposed between the first metal lines 186′ and the second metal lines 184 to form electrical connections therebetween, and a plurality of second connection portions 183 interposed between the second metal lines 184 and the common source lines 180 to form electrical connections therebetween. The first connection portions 185-1 penetrate through a fifth interlayer insulating layer 124 to be connected to the second metal lines 184. The second connection portions 183 penetrate through a third interlayer insulating layer 122 to be connected to the common source lines 180. The source strapping lines 194 are disposed at a first interval S1 in the first direction. The first connection portions 185-1 are disposed at a second interval S2, narrower than the first interval S1. The second connection portions 183 are disposed at a third interval S3, narrower than the first interval S1. The second interval S2 may be substantially equal to the third interval S3. The second connection portions 183 and the gate contact plugs 171 may be simultaneously formed. Upper surface of the second connection portions 183 may be formed on the same level as upper surfaces of the gate contact plugs 171 in the vertical direction.

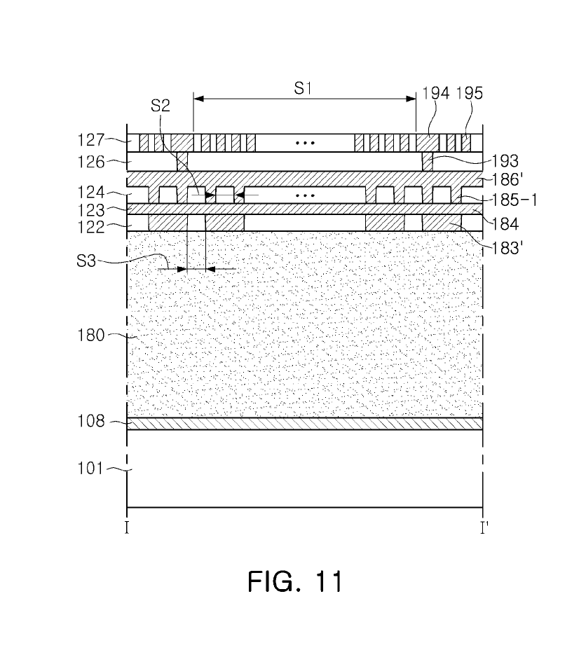

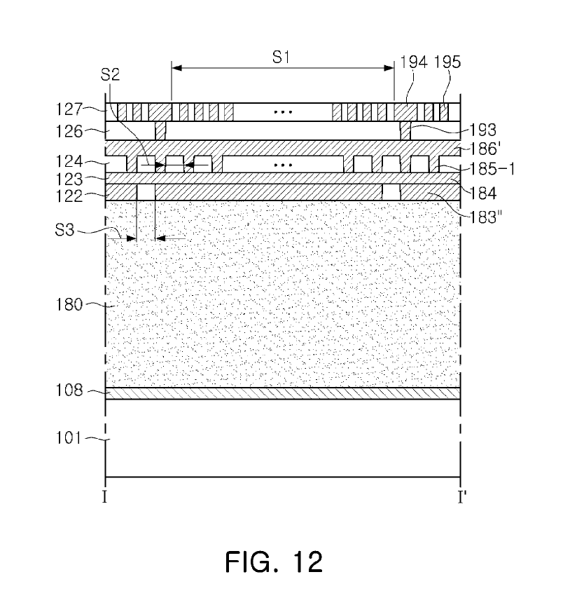

The first connection portions 185-1 and the second connection portions 183 may have a circular horizontal cross section. Alternatively, with reference to FIG. 11, the first connection portions 185-1 may have a circular horizontal cross section. A plurality of second connection portions 183′ are further extended in the first direction, as compared with the second connection portions 183 of FIG. 9 and may have an oval horizontal cross section. Alternatively, with reference to FIG. 12, the plurality of first connection portions 185-1 may have a circular horizontal cross section. A plurality of second connection portions 183″ may be further extended in the first direction, as compared with the second connection portions 183′ of FIG. 11 and may have a rectangular horizontal cross section.

Alternatively, the first connection portions 185-1 may have an oval or rectangular horizontal cross section, while the second connection portions 183 may have a circular horizontal cross section.

Alternatively, an entirety of the plurality of first connection portions 185-1 and the plurality of second connection portions 183 may have an oval horizontal cross section or a rectangular horizontal cross section.

According to example embodiments, contact resistance between the common source lines 180 and the second connection portion 183, the second connection portion 183′, or the second connection portion 183″ may be reduced, and noise may be reduced in the common source lines 180.

With reference to an enlarged view of FIG. 9, the first metal lines 186′ and the first connection portions 185-1 may be formed using a dual damascene process. The second metal lines 184, the second connection portions 183, the contact plugs 193, the source strapping lines 194, and the bit lines 195 may be formed using a single damascene process. Alternatively, in an example embodiment, the first metal lines 186′ and the first connection portions 185-1 may be formed using a single damascene process. Barrier layers 183a, 184a, 185a-1, 186a′, 193a, and 194a may include a conductive metal nitride, such as TiN, while metal layers 183b, 184b, 185b-1, 186b′, 193b, and 194b may include a metal, such as W.

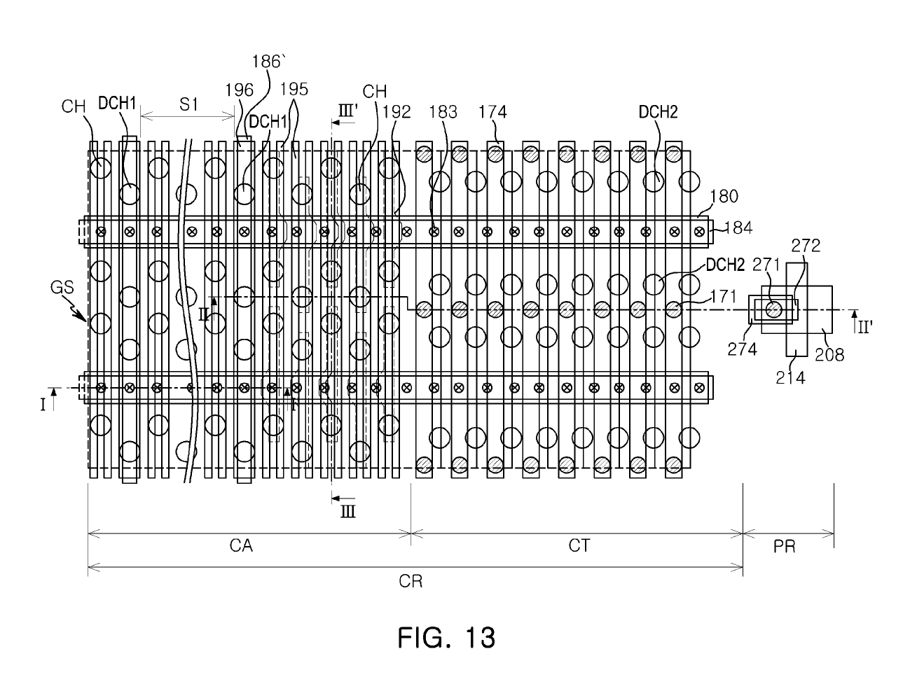

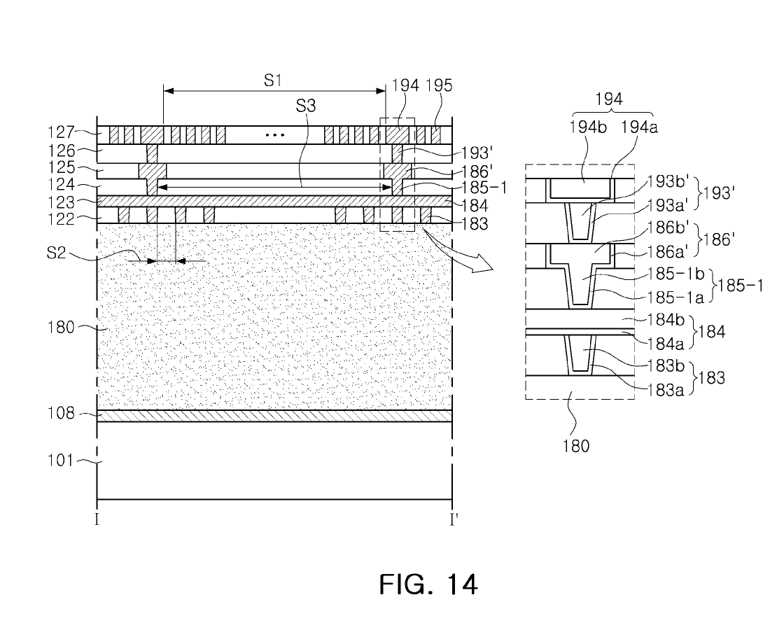

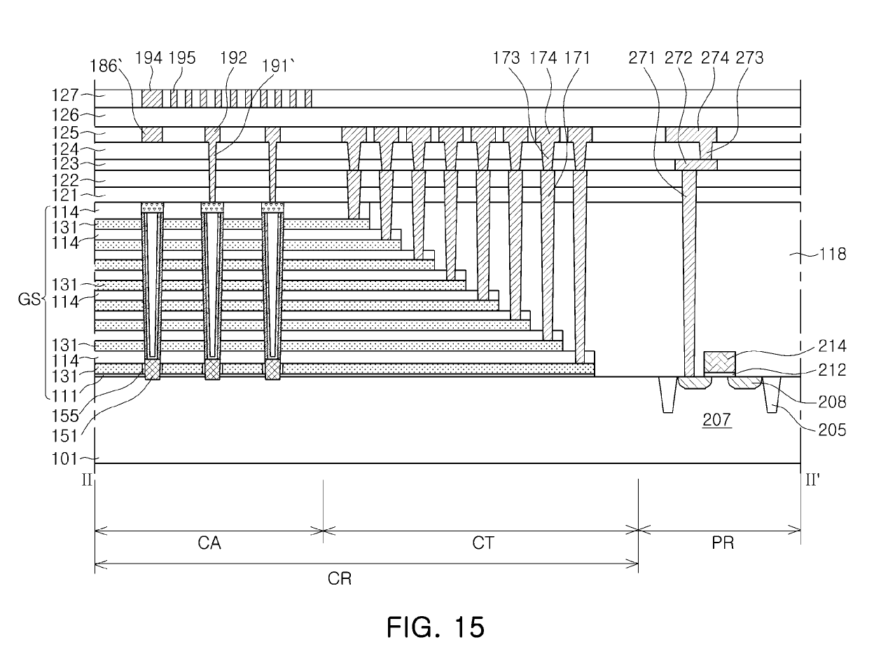

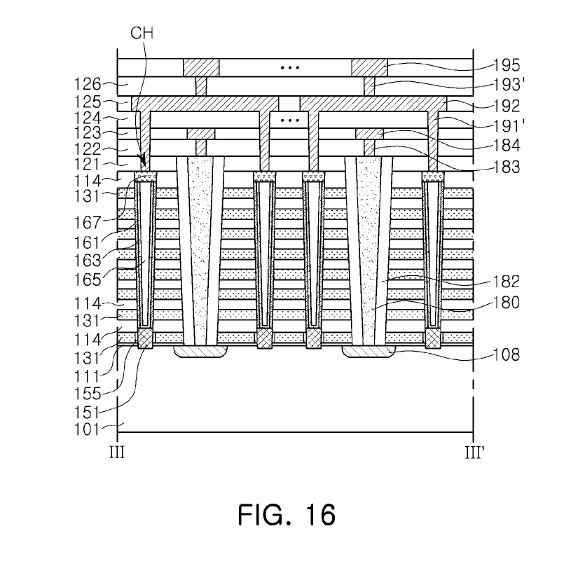

FIG. 13 is a schematic top view of a vertical memory device according to another example embodiment. FIGS. 14 to 16 are schematic cross-sectional views of a vertical memory device according to another example embodiment. FIG. 14 is a cross-sectional view taken along line I-I′ of FIG. 13, FIG. 15 is a cross-sectional view taken along line II-II′ of FIG. 13, and FIG. 16 is a cross-sectional view taken along line of FIG. 13.

The vertical memory device illustrated in FIGS. 14 to 16 will be described, as compared with the vertical memory device illustrated in FIGS. 2 to 5, based on differences therebetween. Unlike the vertical memory device illustrated in FIGS. 2 to 5, the vertical memory device illustrated in FIGS. 14 to 16 may include two metal lines on the common source lines 180. In addition, the vertical memory device includes a plurality of sub-bit lines 192 commonly connected to two first channel contact plugs of a plurality of first channel contact plugs 191′ disposed adjacent to each other in the second direction on both sides of each of the common source lines 180. For example, the sub-bit lines 192 each connects electrically two channel structures of the channel structures CH. The two channel structures are adjacent to each other in the second direction. In this case, the vertical memory device includes a plurality of second channel contact plugs 193′ connecting the bit lines 195 to the sub-bit lines 192.

With reference to FIGS. 14 to 16, the vertical memory device includes a plurality of first metal lines 186′ extended on the common source lines 180 in the second direction intersecting the first direction and a plurality of second metal lines 184 extended in the first direction. The second metal lines 184 are disposed between the first metal lines 186′ and the common source lines 180 and may be extended in the first direction. In addition, the vertical memory device includes a plurality of first connection portions 185-1 interposed between the first metal lines 186′ and the second metal lines 184 to form electrical connections therebetween, and a plurality of second connection portions 183 interposed between the second metal lines 184 and the common source lines 180 to form electrical connections therebetween. The first connection portions 185-1 penetrate through a fifth interlayer insulating layer 124 to be connected to the second metal lines 184. The second connection portions 183 penetrate through a third interlayer insulating layer 122 to be connected to the common source lines 180. The source strapping lines 194 are disposed at a first interval Si in the first direction. The first metal lines 186′ are disposed at an interval substantially equal to that of the source strapping lines 194. The first metal lines 186′ are extended in the same direction as the source strapping lines 194. The first metal lines 186′ and the source strapping lines 194 overlap vertically each other. The first connection portions 185-1 are disposed in the first direction at a third interval S3 greater than the first interval S1. The second connection portions 183 are disposed in the first direction at a second interval S2 narrower than the first interval S1. The second connection portions 183 and the gate contact plugs 171 may be simultaneously formed. Upper surfaces of the second connection portions 183 may be disposed on the same level as upper surfaces of the gate contact plugs 171 in the vertical direction. For example, the upper surfaces of the second connection portions 183 and the upper surfaces of the gate contact plugs 171 are disposed on the same level as an upper surface of the third interlayer insulating layer 122 in the vertical direction. Upper surfaces of the first metal lines 186′ may be disposed on the same level as upper surfaces of the sub-bit lines 192 in the vertical direction. For example, the upper surfaces of the first metal lines 186′ and the sub-bit lines 192 are disposed on the same level as an upper surface of a sixth interlayer insulating layer 125 in the vertical direction.

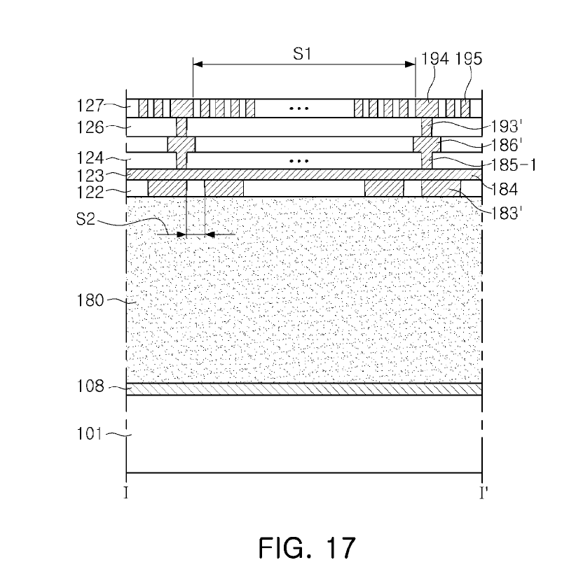

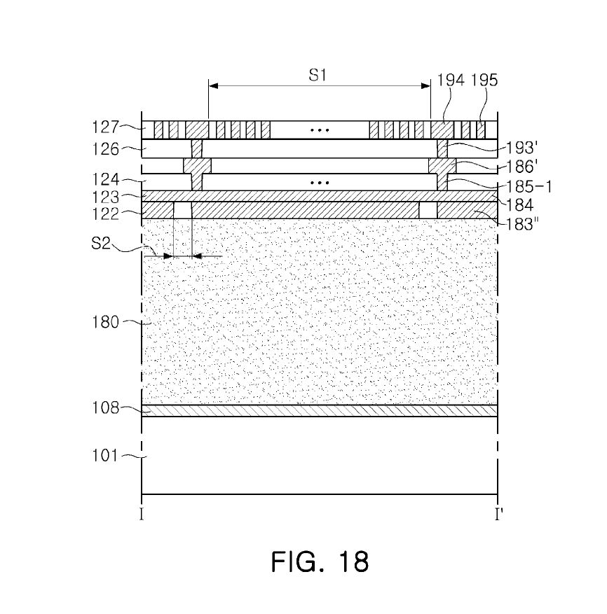

The first connection portions 185-1 and the second connection portions 183 may have a circular horizontal cross section. Alternatively, with reference to FIG. 17, the first connection portions 185-1 may have a circular horizontal cross section. A plurality of second connection portions 183′ may be further extended in the first direction, as compared with the plurality of second connection portions 183 of FIG. 14 and may have an oval horizontal cross section. Alternatively, with reference to FIG. 18 the first connection portions 185-1 may have a circular horizontal cross section. A plurality of second connection portions 183″ may be further extended in the first direction, as compared with the second connection portions 183′ of FIG. 17 and may have a rectangular horizontal cross section.

According to example embodiments, contact resistance between the common source lines 180 and the second connection portions 183, the second connection portions 183′, or the second connection portions 183″ may be reduced, and noise of the common source line 180 may be reduced.

With reference to an enlarged view of FIG. 14, the first metal lines 186′ and the first connection portions 185-1 may be formed using a dual damascene process. The second metal lines 184, the second connection portions 183, the contact plugs 193, the source strapping lines 194, and the bit lines 195 may be formed using a single damascene process. Alternatively, in an example embodiment, the first metal lines 186′ and the first connection portions 185-1 may be formed using a single damascene process. Barrier layers 183a, 184a, 185a-1, 186a′, 193a′, and 194a may include a conductive metal nitride, such as TiN, while metal layers 183b, 184b, 185b-1, 186b′, 193b′, and 194b may include a metal, such as W.

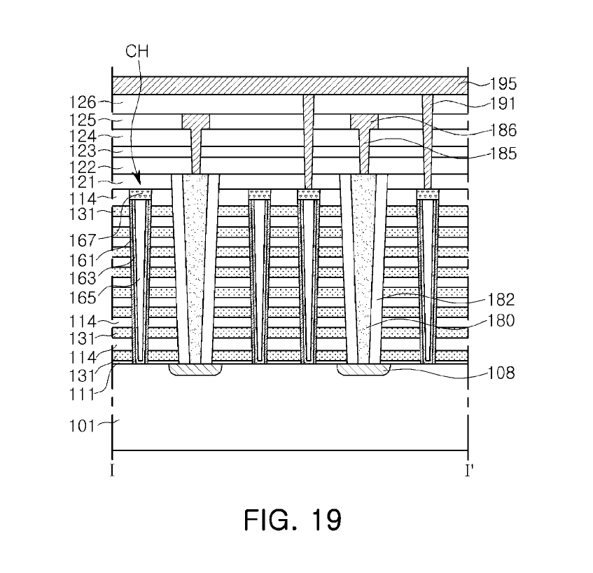

FIGS. 19 to 21 are schematic cross-sectional views of a vertical memory device according to further example embodiments.

The vertical memory device illustrated in FIG. 19 will be described, compared with the vertical memory device illustrated in FIGS. 2 to 5 based on differences therebetween. Unlike the vertical memory device illustrated in FIGS. 2 to 5, the vertical memory device illustrated in FIG. 14 need not include the epitaxial layer 151 and the ground selection gate insulating layer 155 of FIGS. 2 to 5.

Thus, a lower end of the channel layer 163 is in direct contact with a substrate 101. In addition, a lower end of the gate insulating layer 161 is in direct contact with the substrate 101.

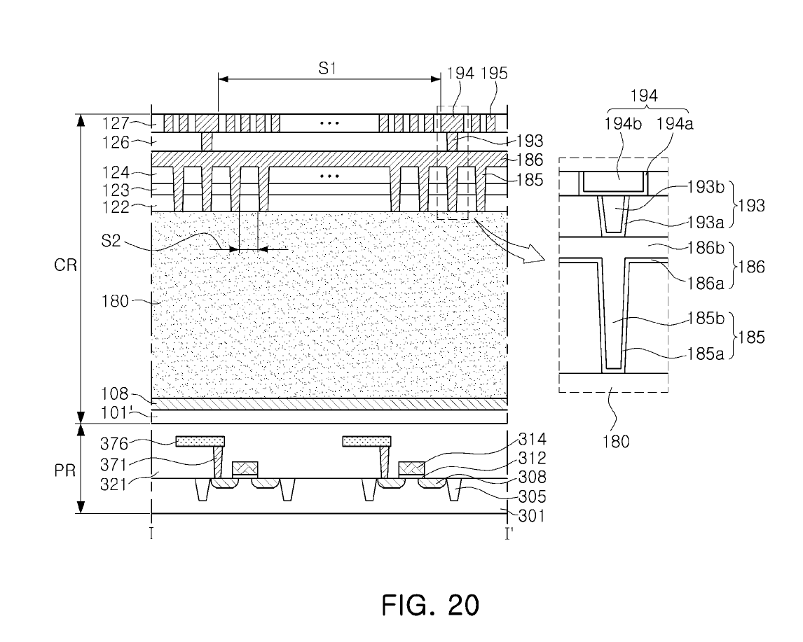

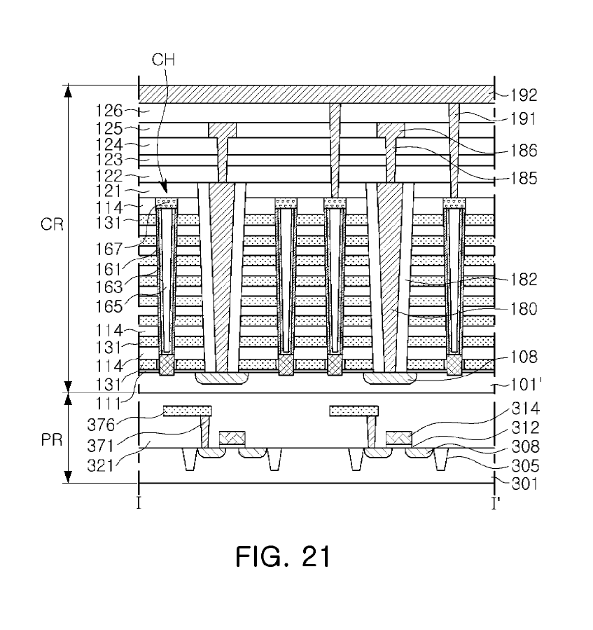

The vertical memory device illustrated in FIGS. 20 to 21 will be described, compared with the vertical memory device illustrated in FIGS. 2 to 5 based on differences therebetween. Unlike the vertical memory device illustrated in FIGS. 2 to 5, the vertical memory device illustrated in FIGS. 20 to 21 may have a structure in which the peripheral circuit region PR is disposed below the cell region CR.

Circuit transistors including a circuit gate insulating layer 312, a circuit gate electrode 314, and a source/drain region 308 are disposed on a first substrate 301. A contact plug 371 connected to the source/drain region 308 and a circuit wiring 376 are disposed in the peripheral circuit region PR below the cell region CR. The cell region CR is disposed on a second substrate 101′ that is on an interlayer insulating layer 321.

In detail, the second substrate 101′ may be formed of polycrystalline silicon.

As set forth above, according to example embodiments of the present inventive concept, a vertical memory device having a reduced level of contact resistance and noise in a common source line thereof may be provided.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A vertical memory device, comprising:
a gate structure including a plurality of gate electrode layers stacked on a substrate;
a plurality of channel structures penetrating through the gate structure and extending in a vertical direction perpendicular to an upper surface of the substrate;
a common source line penetrating the gate structure and extending in a first direction;
a metal line extended above the common source line in the first direction; and
a plurality of connection portions interposed between the metal line and the common source line.

2. The vertical memory device of claim 1,
wherein the common source line is formed of polycrystalline silicon doped with an impurity, and
wherein the plurality of connection portions have a circular, oval, or rectangular horizontal cross section.

3. The vertical memory device of claim 1, further comprising:
a plurality of source strapping lines electrically connected to the metal line, disposed at a first interval in the first direction, and extended in a second direction intersecting the first direction,
wherein the plurality of connection portions are disposed at a second interval in the first direction, narrower than the first interval, and
wherein the plurality of connection portions connect electrically the metal line to the common source line.

4. The vertical memory device of claim 3, further comprising:
a plurality of bit lines electrically connected to the plurality of channel structures,
wherein the metal line is disposed between the plurality of bit lines and the common source line in the vertical direction.

5. The vertical memory device of claim 4,
wherein the plurality of source strapping lines are disposed on the same level as the plurality of bit lines in the vertical direction.

6. The vertical memory device of claim 1,
wherein the metal line is provided as a first metal line, and the plurality of connection portions are provided as a plurality of first connection portions,
the vertical memory device further comprising:
a second metal line electrically connected to the plurality of first connection portions, interposed between the first metal line and the common source line, and extended in the first direction; and
a plurality of second connection portions connecting electrically the second metal line to the common source line,
wherein the plurality of second connection portions are in contact with the common source line.

7. The vertical memory device of claim 6,
wherein the plurality of first connection portions have a circular, oval, or rectangular horizontal cross section.

8. The vertical memory device of claim 6,
wherein the plurality of second connection portions have a circular, oval, or rectangular horizontal cross section.

9. The vertical memory device of claim 6, further comprising:
a plurality of source strapping lines electrically connected to the first metal line and disposed at a first interval in the first direction,
wherein the plurality of first connection portions are disposed in the first direction at a second interval narrower than the first interval, and
wherein the plurality of second connection portions are disposed in the first direction at the second interval.

10. The vertical memory device of claim 6, further comprising:
a plurality of gate contact plugs connected to the plurality of gate electrode layers,
wherein upper surfaces of the plurality of second connection portions are disposed on the same level as upper surfaces of the gate contact plugs in the vertical direction.

11. The vertical memory device of claim 1,
wherein the metal line is provided as a second metal line, and the plurality of connection portions are provided as a plurality of second connection portions,
the vertical memory device further comprising:
a plurality of first metal lines disposed on the second metal line at a first interval in the first direction and extended in a second direction intersecting the first direction; and
a plurality of first connection portions connecting electrically the plurality of first metal lines to the second metal line,
wherein the plurality of second connection portions are disposed in the first direction at a second interval, narrower than the first interval and the plurality of first connection portions are disposed in the first direction at a third interval greater than the first interval.

12. The vertical memory device of claim 11,
wherein the plurality of second connection portions have a circular, oval, or rectangular horizontal cross section.

13. The vertical memory device of claim 11, further comprising:
a plurality of sub-bit lines each connecting two channel structures among the plurality of channel structures,
wherein upper surfaces of the plurality of first metal lines are disposed on the same level as upper surfaces of the plurality of sub-bit lines in the vertical direction.

14. The vertical memory device of claim 11, further comprising:
a plurality of gate contact plugs connected to the plurality of gate electrode layers,
wherein upper surfaces of the plurality of second connection portions are disposed on the same level as upper surfaces of the plurality of gate contact plugs in the vertical direction.

15. A vertical memory device, comprising:
a plurality of gate electrode layers stacked in a vertical direction on a substrate;
a common source line penetrating the plurality of gate electrode layers and extended in a first direction;
at least one metal line disposed above the common source line; and
a plurality of connection portions interposed between the at least one metal line and the common source line.

16. The vertical memory device of claim 15, further comprising:
a plurality of source strapping lines electrically connected to the at least one metal line, disposed at a first interval in the first direction, and extended in a second direction intersecting the first direction,
wherein the plurality of connection portions are disposed at a second interval, narrower than the first interval.

17. The vertical memory device of claim 15, further comprising:
a plurality of gate contact plugs connected to the plurality of gate electrode layers,
wherein an upper surface of the plurality of connection portions is disposed at the same level as an upper surface of the gate contact plugs in the vertical direction.

18. The vertical memory device of claim 15,
wherein the common source line is formed of polycrystalline silicon doped with an impurity, and
wherein the at least one metal line includes a metal line extended above the common source line in the first direction.

19. The vertical memory device of claim 18,
wherein the common source line is connected to an impurity region disposed within the substrate,
wherein the impurity of the common source line and an impurity of the impurity region are of the same type, and
wherein an impurity concentration of the common source line is higher than an impurity concentration of the impurity region.

20. A vertical memory device, comprising:
a plurality of gate electrode layers stacked on a substrate;
a common source line penetrating the plurality of gate electrode layers and extended in a first direction;
at least one metal line extended in the first direction and disposed above the common source line;
a plurality of source strapping lines disposed on the at least one metal line at a first interval in the first direction; and
a plurality of connection portions interposed between the at least one metal line and the common source line at a second interval, narrower than the first interval,
wherein the plurality of connection portions are in contact with the common source line, and
wherein the plurality of source strapping lines are electrically connected to the at least one metal line.
